(19) United States
(12) Patent Application Publication
(10) Pub. No.: US 2012/0086029 A1
(43) Pub. Date: Apr. 12, 2012

(54) LIGHT-EMITTING DIODE DEVICE AND MANUFACTURING METHOD THEREOF

(76) Inventors: Kuo-Hui YU, Tainan City (TW); Chang-Hsin Chu, Tainan City (TW)

(21) Appl. No.: 13/037,827

(22) Filed: Mar. 1, 2011

(30) Foreign Application Priority Data
Oct. 6, 2010 (TW) 099134107

(51) Int. Cl. H01L 33/46

(52) U.S. Cl. 257/98; 438/29; 257/E33.06; 257/E33.068

(57) ABSTRACT

A light-emitting diode (LED) device includes a substrate and an epitaxial layer which is disposed on a surface of the substrate. A depression is disposed to a sidewall of the LED device, and a reflective layer is disposed to on least one portion of the depression. By the reflective layer disposed to the depression of the sidewall of the LED device, the light loss caused by the interface of the substrate and the epitaxial layer can be reduced, the light absorbed by the substrate can be decreased, and the angle of the light exiting from the LED device can be adjusted. A manufacturing method of the LED device is also disclosed.

### CROSS REFERENCE TO RELATED APPLICATIONS

This Non-provisional application claims priority under 35 U.S.C. §119(a) on Patent Application No(s). 099134107 filed in Republic of China on Oct. 6, 2010, the entire contents of which are hereby incorporated by reference.

### BACKGROUND OF THE INVENTION

1. Field of Invention

The invention relates to a light-emitting diode device and a manufacturing method thereof and, in particular, to a light-emitting diode device having a reflecting layer disposed on a sidewall thereof.

2. Related Art

Light-emitting diodes (LED), made of semiconductor material, have advantages such as low power consumption, long lifespan, and fast response. In addition, since the LEDs can be easily manufactured to a small device or an array device, they are widely applied to various appliances, such as indicators of the computers or the household appliances, backlights of the LCD apparatuses, traffic lights and vehicle lights.

FIG. 1 is a schematic diagram of a conventional LED device 1. As shown in FIG. 1, the LED 1 includes a substrate 11, an N-type semiconductor layer 12, a multiple quantum well (MQW) structure 13, a P-type semiconductor layer 14, a transparent conductive layer 15, a first electrode 16 and a second electrode 17. The first and second electrodes 16 and 17 are respectively disposed to the N-type semiconductor layer 12 and the P-type semiconductor layer 14, and were bonded with conductive wires to receive driving signal, which controls the LED device 1 to emit light.

However, due to mismatch of refraction indexes of the substrate 11 and the epitaxial layer, the light generated by the LED device 1 is easily consumed at the interface, and the output of the light is thus decreased. Besides, if there is a need to change the direction of the light emitting from the LED device 1, an additional reflective structure, such as a reflective cup, needs to be disposed around the LED device 1. However, this not only increases the steps of manufacturing but also is unfavorable to the compactness.

Therefore, it is an important subject to provide a light-emitting diode device that can decrease consumption of the light at the interface, and the direction of the light emitted from the LED device can be adjusted by the light-emitting diode device itself.

### SUMMARY OF THE INVENTION

In view of the foregoing subject, an objective of the invention is to provide a light-emitting diode device that can decrease the consumption of the light at the interface, and the direction of the light emitted from the LED device can be adjusted by itself, so as to help the compactness and decrease the manufacturing period, and further enhance production competitiveness.

To achieve the above objective, a light-emitting diode device of the invention includes a substrate and an epitaxial layer disposed on a surface of the substrate. A depression is disposed on a sidewall of the light-emitting diode device, and a reflective layer is disposed to on least one portion of the depression.

In one embodiment, the epitaxial layer includes a first conductivity type semiconductor layer, a light-emitting layer and a second conductivity type semiconductor layer. The first conductivity type semiconductor layer is located between the light-emitting layer and the substrate. The depression is located on the first conductivity type semiconductor layer or the substrate, or between the first conductivity type semiconductor layer and the substrate. In the invention, the depression can be disposed on various positions so as to achieve different effects of decreasing light consumption and adjusting light-emitting direction.

In one embodiment, the reflective layer is further disposed on the surface of the substrate, or on the sidewall. By extending the reflective layer to the surface or the sidewall, the light consumption of the device can be further decreased and the light-emitting direction of the LED device can be further adjusted.

In one embodiment, the reflective layer is an insulated reflective layer. Because the reflective layer can be extended to the first and second conductivity type semiconductor layers, the insulated reflective layer can avoid a short circuit therebetween.

In one embodiment, the reflective layer includes a reflective material or a reflective structure. By the reflective material, reflective structure or the combination thereof, different effects on the reflection can be achieved.

In one embodiment, the LED device further includes a first electrode disposed on the first conductivity type semiconductor layer and a second electrode disposed on the second conductivity type semiconductor layer. The depression doesn't overlap with the first electrode or the second electrode along a vertical direction, i.e. a direction perpendicular to the surface of the substrate. Because the depression is restrained from overlapping with the first or second electrodes along a vertical direction, the structure strength of the LED device can be maintained to a certain level to avoid the decrease of the production yield.

In one embodiment, a height of the depression is not larger than half thickness of the first conductivity type semiconductor layer so as to maintain the structure strength of the LED device to a certain level to prevent from the decrease of the production yield.

In one embodiment, the depression has a flat surface or a curved surface. The flat surface, the curved surface or combination thereof can provide different effects of decreasing light consumption and adjusting light-emitting direction, so as to increase the applications of the production.

To achieve the above objective, a manufacturing method of a light-emitting diode device includes the steps of forming an epitaxial layer on a surface of a substrate; forming a depression on a sidewall of the substrate and the epitaxial layer; and forming a reflective layer on the depression.

In one embodiment, the depression is formed by wet etching or the combination of wet etching and laser illumination. Laser illumination causes the separation of the substrate and the epitaxial layer, facilitating the lateral etching with the etchant to enhance the etching efficiency.

As mentioned above, a depression is formed on the sidewall of the LED device and a reflective layer is formed on the depression in the invention, so the light generated by the LED device can be reflected through the reflective layer, resulting in decreasing the light consumption occurred at the interface of the substrate and the epitaxial layer and the light absorbed by the substrate, and adjusting the light-emitting direction of the LED device. Besides, because the light-emitting direction can be adjusted by the LED device itself, the LED device is favorable for the compactness with a shortened manufacturing period, and thus the production competitiveness can be enhanced.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram of a conventional LED device;

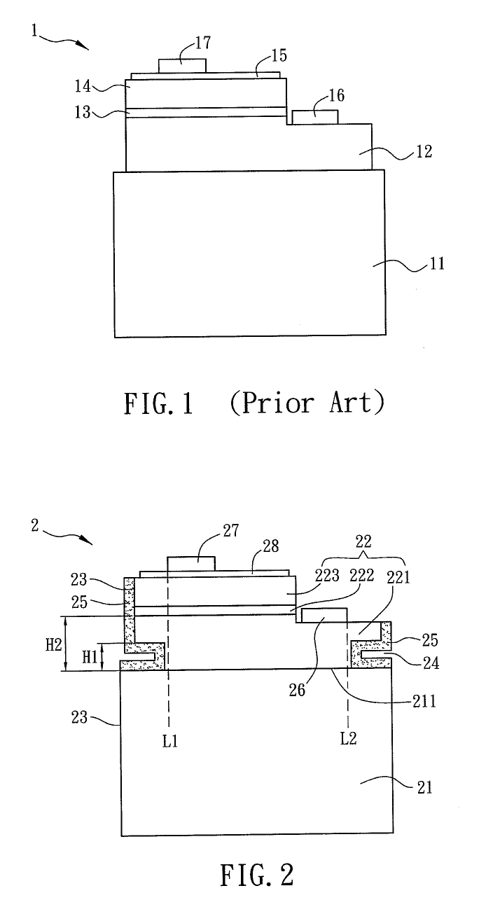

FIG. 2 is a schematic diagram of a light-emitting diode device of a preferred embodiment of the invention;

FIGS. 3A to 3D are schematic diagrams of various LED devices of the invention;

FIG. 4 is flow chart of a manufacturing method of the LED device of a preferred embodiment of the invention;

FIGS. 5A to 5D are schematic diagrams of a manufacturing method of the LED device of a preferred embodiment of the invention; and

FIGS. 6A and 6B are schematic diagrams of a manufacturing method of another LED device of a preferred embodiment of the invention.

### DETAILED DESCRIPTION OF THE INVENTION

The present invention will be apparent from the following detailed description, which proceeds with reference to the accompanying drawings, wherein the same references relate to the same elements.

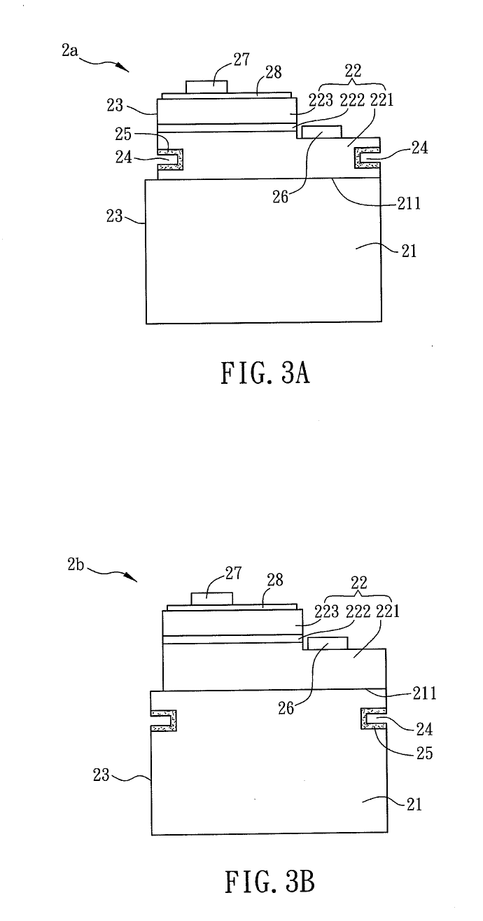

FIG. 2 is a schematic diagram of a light-emitting diode (LED) device 2 of a preferred embodiment of the invention. As shown in FIG. 2, the LED device 2 includes a substrate 21 and an epitaxial layer 22 which is disposed on a surface 211 of the substrate 21. Besides, a depression 24 is disposed on a sidewall 23 of the LED device 2, and a reflective layer 25 is disposed to on least one portion of the depression 24.

The material of the substrate 21 is not limited in the embodiment, which can include, for example, sapphire, SiC, GaP or Si. Here, the substrate 21 is made of sapphire for example.

The epitaxial layer 22 is disposed on the substrate 21. The epitaxial layer 22 is a semiconductor layer formed by epitaxy technology, including a first conductivity type semiconductor layer 221, a light-emitting layer 222 and a second conductivity type semiconductor layer 223, for example. The first conductivity type semiconductor layer 221 is disposed between the light-emitting layer 222 and the substrate 21. For example, the first conductivity type semiconductor layer 221 is an N-type semiconductor layer, and the second conductivity type semiconductor layer 223 is a P-type semiconductor layer. With different types of the LED device 2, such as blue LED, green LED or red LED, the epitaxial layer 22 can be made of various materials. The material of the epitaxial layer 22 can include, for example, GaN or AlInGaP. Besides, the light-emitting layer 222 is, for example, a multiple quantum well (MQW) structure for generating the required color of the light.

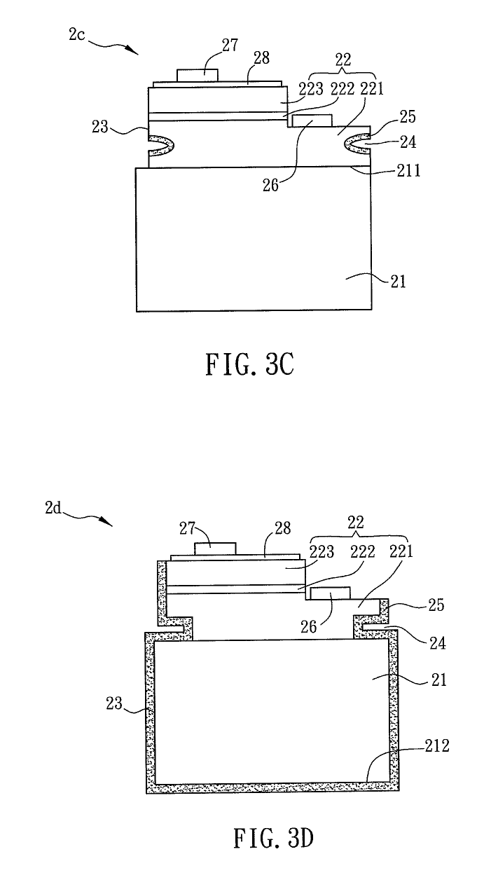

In the embodiment, the depression 24 can be located on the first conductivity type semiconductor layer 221 (referring to the LED device 2a in FIG. 3A), or between the first conductivity type semiconductor layer 221 and the substrate 21 (as shown in FIG. 2), or on the substrate 21 (referring to the LED device 2b in FIG. 3B). In the embodiment, the depression 24 can be disposed on various positions so as to achieve different effects of decreasing the light consumption and adjusting the light-emitting direction. The depression 24 can have a flat surface, a curved surface or combination thereof. The aspect of the flat surface is shown in FIG. 2, and the aspect of the curved surface is shown as the LED device 2c in FIG. 3C. The flat surface, the curved surface or combination thereof can cause different effects of decreasing the light consumption and adjusting the light-emitting direction, so as to increase the applications of the product.

As shown in FIG. 2, in the embodiment, a height H1 of the depression 24 is not larger than half thickness H2 of the first conductivity type semiconductor layer 221, so that the structure strength of the LED device 2 can be maintained to a certain level to prevent from decreasing the production yield. The LED device 2 further includes a first electrode 26 disposed on the first conductivity type semiconductor layer 221 and a second electrode 27 disposed on the second conductivity type semiconductor layer 223. The depression 24 doesn't overlap with the first electrode 26 and/or the second electrode 27 along a vertical direction, i.e. a direction perpendicular to the surface 211 of the substrate 21. For example, the depression 24 as shown in FIG. 2 is disposed outside the range delimited by the dotted lines L1 and L2, and on the peripheral portion or partial of the peripheral portion of the LED device 2. Because the depression is restrained from overlapping with the first or second electrodes 26 and 27 along the vertical direction, the structure strength of the LED device 2 can be maintained to a certain level to avoid the decrease in the production yield. For example, by limiting the position of the depression 24 to the peripheral portion of the LED device 2, the chip can be prevented from being broken during the wire bonding process.

The reflective layer 25 can include reflective material or reflective structure. Reflective effects with different levels can be achieved by alternatively selecting reflective material, reflective structure or combination thereof. As shown in FIG. 2, the reflective layer 25 is disposed on the depression 24, and further extended to the surface 211 of the substrate or the sidewall 23. By extending the reflective layer 25 to the surface 211 or the sidewall 23, light consumption of the device can be further decreased and light-emitting direction of the device can be further adjusted. Besides, because the reflective layer 25 can be extended to the first and second conductivity type semiconductor layers 221 and 223, the reflective layer 25 can also be made of insulating material, such as Al₂O₃, TiO₂ or HfO₂, to avoid short circuit issue. Alternatively, if the reflective layer 25 is not extended to the second conductivity type semiconductor layer 223, it can be made of metal or alloy material, such as Ag, Al or Pt.

FIG. 3D is a schematic diagram of an LED device 2d of another aspect. The reflective layer 25 of the LED device 2d covers the exposed portion of the substrate 2, which is, for example, the sidewall 23 and a bottom surface 212 of the substrate 21. Accordingly, the light-emitting direction of the device can be further adjusted. To be noted, the reflective layer of the LED device 2d is preferably made of insulating material to prevent the first and second conductivity type semiconductor layers from being short-circuited.

Furthermore, in the embodiment, the LED devices 2 and 2a-2d can further include a transparent conductive layer (TCL) 28. The TCL 28 is disposed on the epitaxial layer 22, and the second electrode 27 is disposed on the TCL 28.

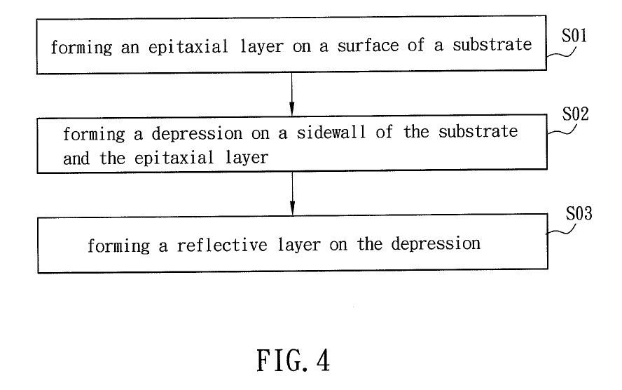

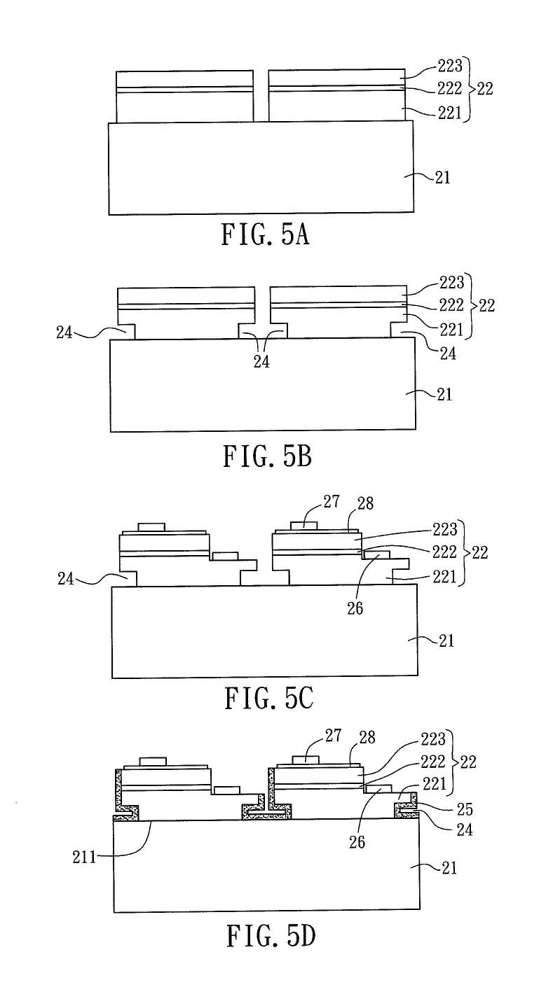

FIG. 4 is a flow chart of a manufacturing method of the invention, including the step S01 to the step S03, and FIGS. 5A to 5D are schematic diagrams for demonstrating the manufacturing method. Referring to FIG. 4 and FIGS. 5A to 5D, the manufacturing method of the LED device 2 is illustrated as follows.

As shown in FIG. 5A, first, an epitaxial layer 22 is formed on a substrate 21 by MOCVD (metalorganic chemical vapor deposition) for example. The epitaxial layer 22 can include a first conductivity type semiconductor layer 221, a light-emitting layer 222 and a second conductivity type semiconductor layer 223.

Then, as shown in FIG. 5B, a depression 24 is formed on a sidewall 23 of the substrate 21 and the epitaxial layer 22 (the step S02). The depression 24 can be located on the first conductivity type semiconductor layer 221, or between the first conductivity type semiconductor layer 221 and the substrate 21, or on the substrate 21. Besides, a height of the depression 24 is preferably not larger than half thickness of the first conductivity type semiconductor layer 221. The depression 24 can be formed by wet etching or the combination of wet etching and laser illumination. The laser illumination can be conducted from a side of the substrate 21, and can be implemented within a limited range of the device. Preferably, the device is illuminated by the laser before the wet etching is conducted. By the laser illumination, the substrate 21 can be separated from the epitaxial layer 22 so as to facilitate the lateral etching of the etchant to enhance the etching efficiency.

Next, as shown in FIG. 5C, partial of the second conductivity type semiconductor layer 223, light-emitting layer 222 and the first conductivity type semiconductor layer 221 are etched to expose said partial of the first conductivity type semiconductor layer 221, so that the first electrode 26 can be formed on the exposed portion of the first conductivity type semiconductor layer 221. Additionally, a transparent conductive layer 28 is formed on the second conductivity type semiconductor layer 223, and a second electrode 27 is formed over the second conductivity type semiconductor layer 223 and the transparent conductive layer 28. To be noted, the depression 24 doesn't overlap with the first electrode 26 and/or the second electrode 27 along a vertical direction, i.e. a direction perpendicular to the surface 211 of the substrate 21.

Then, as shown in FIG. 5D, a reflective layer 25 is formed on the depression 24 by, for example, ALD (Atomic Layer Deposition) or AVD (Atomic Vapor Deposition). The reflective layer 25 can be further formed on the surface 211 of the substrate 21 and sidewall 23 of both the substrate 21 and the epitaxial layer 22. The reflective layer 25 can include reflective material or reflective structure, and also the reflective layer 25 can include insulating material. Because the features of the reflective layer 25 are illustrated clearly as the above embodiments, the detailed descriptions thereof are omitted. In the embodiment, two LED devices are formed on the substrate 21 as shown in FIG. 5D, such that substrate 21 of FIG. 5D needs to be separated to obtain the LED device 2 as shown in FIG. 2.

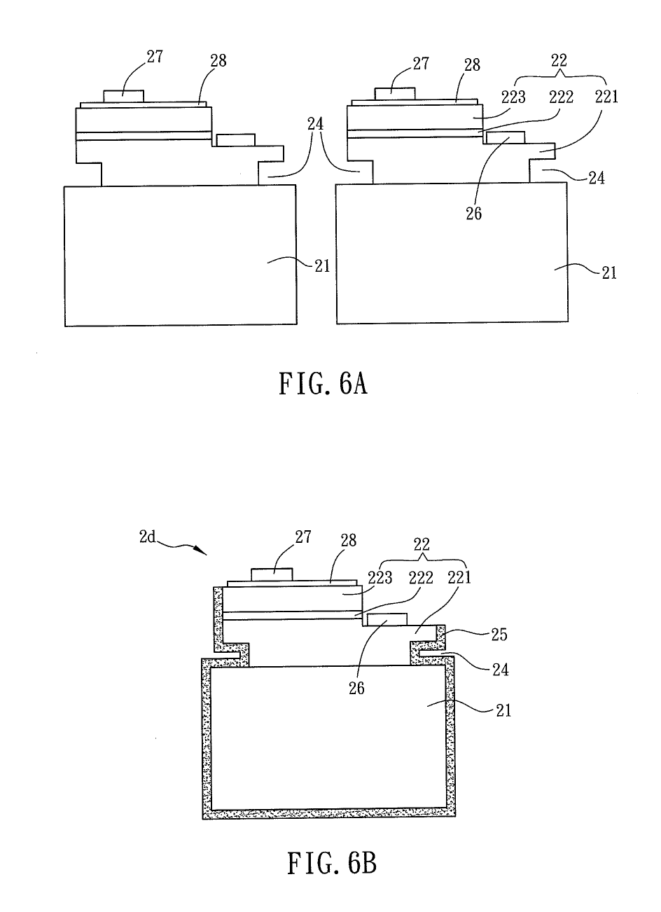

FIGS. 6A and 6B are schematic diagrams demonstrating the manufacturing method of the LED device 2d. To be noted, the manufacturing method of the LED device 2d also can include the steps shown in FIGS. 5A to 5C, which are omitted in the following descriptions.

Following FIG. 5C, a separation step is conducted for separating the substrate 21 to obtain two semi-manufactured LED devices as shown in FIG. 6A. The separation step can be conducted by attaching a blue tape to the side of the second electrode 27. Next, as shown in FIG. 6B, a reflective layer 25 is formed on the depression 24. Besides, in this step, the blue tape can act as the mask to form the reflective layer 25 on the exposed portion of the substrate 21 and the depression 24.

In summary, a depression is formed on the sidewall of the LED device and a reflective layer is formed on the depression in the invention, so the light generated by the LED device can be reflected through the reflective layer, resulting in decreasing light consumption occurred at the interface of the substrate and the epitaxial layer, reducing light absorbed by the substrate and adjusting the light-emitting direction of the LED device. Besides, because the light-emitting direction can be adjusted by the LED device itself, the LED device is favorable for the compactness with a shortened manufacturing period, and thus the production competitiveness can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode device, comprising:
a substrate;
an epitaxial layer disposed on a surface of the substrate, wherein a depression is disposed on a sidewall of the light-emitting diode device; and
a reflective layer is disposed on at least one portion of the depression.

2. The light-emitting diode device as recited in claim 1, wherein the epitaxial layer includes a first conductivity type semiconductor layer, a light-emitting layer and a second conductivity type semiconductor layer, the first conductivity type semiconductor layer is located between the light-emitting layer and the substrate, and the depression is located on the first conductivity type semiconductor layer or the substrate, or between the first conductivity type semiconductor layer and the substrate.

3. The light-emitting diode device as recited in claim 1, wherein the reflective layer is disposed on the surface of the substrate, or on the sidewall.

4. The light-emitting diode device as recited in claim 1, wherein the reflective layer is an insulated reflective layer.

5. The light-emitting diode device as recited in claim 1, wherein the reflective layer include reflective material or reflective structure.

6. The light-emitting diode device as recited in claim 1, wherein the reflective layer is extended to the surface, or the sidewall, or a bottom surface of the substrate opposite to the surface.

7. The light-emitting diode device as recited in claim 2, further comprising:
a first electrode disposed on the first conductivity type semiconductor layer; and
a second electrode disposed on the second conductivity type semiconductor layer, wherein the depression doesn't overlap with the first electrode or the second electrode along a direction perpendicular to the surface of the substrate.

8. The light-emitting diode device as recited in claim 2, wherein a height of the depression is not larger than half thickness of the first conductivity type semiconductor layer.

9. The light-emitting diode device as recited in claim 1, wherein the depression has a flat surface or a curved surface.

10. A manufacturing method of a light-emitting diode device, comprising steps of:
forming an epitaxial layer on a surface of a substrate;
forming a depression on a sidewall of the substrate and the epitaxial layer; and
forming a reflective layer on the depression.

11. The manufacturing method of a light-emitting diode device as recited in claim 10, wherein the step of forming the epitaxial layer comprises forming a first conductivity type semiconductor layer, a light-emitting layer and a second conductivity type semiconductor layer sequentially on the substrate, and the depression is located on the first conductivity type semiconductor layer or the substrate, or between the first conductivity type semiconductor layer and the substrate.

12. The manufacturing method of a light-emitting diode device as recited in claim 10, wherein the reflective layer is formed on the surface of the substrate, or on the sidewall of the substrate and the epitaxial layer.

13. The manufacturing method of a light-emitting diode device as recited in claim 10, wherein the reflective layer is formed by ALD (atomic layer deposition) or AVD (atomic vapor deposition).

14. The manufacturing method of a light-emitting diode device as recited in claim 11, wherein a height of the depression is not larger than half thickness of the first conductivity type semiconductor layer.

15. The manufacturing method of a light-emitting diode device as recited in claim 11, further comprising steps of:
forming a first electrode on the first conductivity type semiconductor layer; and
forming a second electrode on the second conductivity type semiconductor layer, so that the depression doesn't overlap with the first electrode or the second electrode along a direction perpendicular to the surface of the substrate.

16. The manufacturing method of a light-emitting diode device as recited in claim 10, wherein the depression is formed by wet etching.

17. The manufacturing method of a light-emitting diode device as recited in claim 10, wherein the depression is formed by wet etching and laser illumination.

18. A light-emitting diode device, comprising:
a substrate;
an epitaxial layer disposed on a surface of the substrate, wherein a depression is disposed on a peripheral portion of the light-emitting diode device; and
a reflective layer is disposed on at least one portion of the depression.

19. The light-emitting diode device as recited in claim 18, wherein the epitaxial layer includes a first conductivity type semiconductor layer, a light-emitting layer and a second conductivity type semiconductor layer, the first conductivity type semiconductor layer is located between the light-emitting layer and the substrate, and the depression is located on the first conductivity type semiconductor layer or the substrate, or between the first conductivity type semiconductor layer and the substrate.

20. The light-emitting diode device as recited in claim 19, further comprising:
a first electrode disposed on the first conductivity type semiconductor layer; and
a second electrode disposed on the second conductivity type semiconductor layer, wherein the depression doesn't overlap with the first electrode or the second electrode along a direction perpendicular to the surface of the substrate.
